(19) United States
(12) Patent Application Publication
(10) Pub. No.: US 2021/0252551 A1
(43) Pub. Date: Aug. 19, 2021

(54) POWDER COATED OR PAINTED GOLF SHAFT AND METHOD OF MANUFACTURING THE SAME

(71) Applicant: TRUE TEMPER SPORTS, INC., Memphis, TN (US)

(72) Inventors: Scott COKEING, Eads, TN (US); Kevin ADAMS, Smithville, MS (US)

(73) Assignee: TRUE TEMPER SPORTS, INC., Memphis, TN (US)

(21) Appl. No.: 17/251,840

(22) PCT Filed: Jun. 28, 2019
(86) PCT No.: PCT/US2019/039730

§ 371 Date: Dec. 14, 2020

Related U.S. Application Data
(60) Provisional application No. 62/695,479, filed on Jul. 9, 2018.

(51) Int. Cl. B05D 1/06; C09D 5/03; A63B 53/12; B05D 3/10; B05D 3/12; C23C 14/00; C23C 14/02; B05D 7/14

(52) U.S. Cl. CPC B05D 1/06; C09D 5/03; A63B 53/12; B05D 3/102; A63B 2209/00; C23C 14/0015; C23C 14/021; B05D 7/146; B05D 2202/10; B05D 3/12

(57) ABSTRACT

A method includes: obtaining a raw steel golf shaft; and applying a colored coating directly to exterior surfaces of the raw steel golf shaft using an applicator. A golf club shaft includes: a raw steel tubular member; and a colored coating applied directly to exterior surfaces of the raw steel tubular member.

### CROSS-REFERENCE TO RELATED APPLICATIONS

This application claims the benefit of U.S. Provisional Application No. 62/695,479, filed on Jul. 9, 2018. The entire disclosure of the application referenced above is incorporated herein by reference.

### FIELD

The present disclosure relates to shafts of golf clubs and more particularly to powder coated or painted steel golf club shafts and methods of manufacturing the same.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

Steel golf shafts are chrome plated.

### SUMMARY

In a feature, a method includes: obtaining a raw steel golf shaft; and applying a colored coating directly to exterior surfaces of the raw steel golf shaft using an applicator.

In further features, the raw steel golf shaft does not include chrome plating.

In further features, the method further includes coupling the raw steel golf shaft to a reference potential, where applying the colored coating includes applying the colored coating by powder coating.

In further features, the method further includes curing the colored coating.

In further features, the method further includes pre-treating the raw steel golf shaft prior to the application of the colored coating.

In further features, the pre-treating includes rust-proofing.

In further features, the pre-treating includes etching.

In further features, the pre-treating includes rinsing.

In further features, the pre-treating includes degreasing.

In further features, the applying the colored coating includes applying a colored paint directly to the exterior surfaces of the raw steel golf shaft.

In further features, the paint includes a solvent based paint.

In further features, the paint includes at least 0.5% acid by volume.

In further features, applying the colored coating includes applying one or more layers of colored film using physical vapor deposition (PVD).

In a feature, a golf club shaft includes: a raw steel tubular member; and a colored coating applied directly to exterior surfaces of the raw steel tubular member.

In further features, the golf club shaft does not include chrome plating between the exterior surfaces of the raw steel tubular member and the colored coating.

In further features, the colored coating includes a colored powder coating.

In further features, the colored coating includes a colored paint.

In further features, the colored coating includes one or more layers of colored film.

In further features, the exterior surfaces of the raw steel tubular member are pre-treated prior to the application of the colored coating.

In further features, the pre-treatment includes at least one of rust-proofing, etching, rinsing, and degreasing.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 includes an example illustration of a powder coating system;

FIG. 2 includes an example illustration of a painting system; and

FIG. 3 includes an example method of applying one or more colored coatings to a raw steel golf (club) shaft.

In the drawings, reference numbers may be reused to identify similar and/or identical elements.

### DETAILED DESCRIPTION

Exterior surfaces of steel golf (club) shafts are chrome plated. The chrome plating provides golf shafts with a finish that is cosmetically acceptable to consumers. The chrome plating also protects golf shafts from scratches, scuffs, and corrosion.

Steel golf shafts could be colored by applying paint (e.g., a solvent based paint), by physical vapor deposition (PVD), or powder coating over the chrome plating. The coloring, however, may be dis-bond, chip, and/or peel away from the chrome plating through normal use. This may be attributable to, for example, low adherence between the chrome plating and the colored coating.

According to the present disclosure, raw steel golf shafts are coated with a colored coating. Raw steel golf shafts do not include chrome plating and have not been chrome plated. For example, raw steel golf shafts can be powder coated or painted using a solvent based paint. As another example, raw steel golf shafts can be coated using PVD. Coatings applied to raw steel golf shafts adhere better to raw steel golf shafts than chrome plated golf shafts. Also, the cost associated with chrome plating can be avoided. A coat of translucent or transparent paint can be applied, for example, to increase a depth of color.

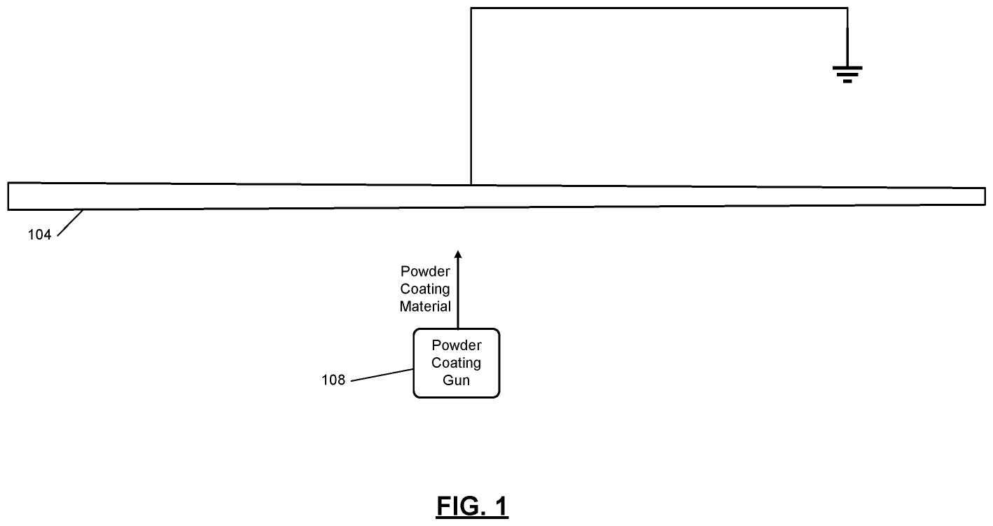

FIG. 1 includes an example illustration of a powder coating system. A raw steel golf (club) shaft 104 is connected to a reference potential, such as a ground potential. For example, the raw steel golf shaft 104 may be hung, using an electrically conductive hanger, from an electrically conductive rack that is connected to the reference potential. Raw steel golf shafts do not include chrome plating and have not been chrome plated. The raw steel golf shaft 104 is a raw steel tubular member and may be tapered or non-tapered.

A powder coating gun (e.g., a corona powder coating gun or a tribo powder coating gun) 108 electrostatically charges powder coating material and sprays the powder coating material onto the raw steel golf shaft 104. The powder coating gun 108 may be moved by a human or a robot to apply the powder coating material over the entire exterior surface of the golf shaft 104. Different types of powder coating material may be used to provide different colored coatings.

One or more pre-treatments may be performed on the raw steel golf shaft 104 prior to the application of the powder coating material onto the raw steel golf shaft 104. Example pre-treatments include rust-proofing, etching, rinsing, degreasing, and other steel pre-treatments. The raw steel golf shaft 104, however, is not chrome plated.

After the powder coating material is applied to the raw steel golf shaft 104, the raw steel golf shaft 104 (coated with the powder coating material) is cured. The curing may involve heating to at least a predetermined temperature for curing the powder coating material.

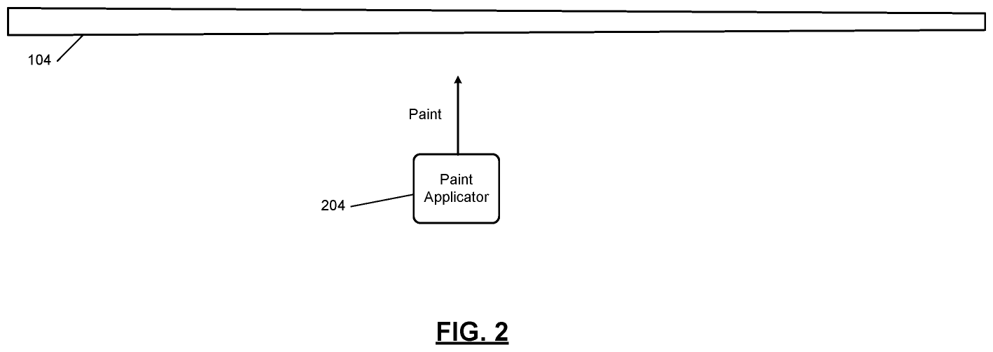

FIG. 2 includes an example illustration of a painting system. In this example, the raw steel golf shaft 104 is painted using a paint applicator 204, such as a paint spray gun or another type of steel golf shaft paint applicator. In various implementations, the raw steel golf shaft 104 may be drawn through an aperture in a painting applicator to apply the paint to the raw steel golf shaft 104. Paint spray guns may be moved by a human or a robot to apply the paint over the entire exterior surface of the raw steel golf shaft 104.

The paint may be a solvent based paint. In various implementations, the paint may include an acid, such as at least 0.5% acid by volume. The acid may help the paint adhere to the raw steel golf shaft 104. Different colors of paint can be applied.

One or more pre-treatments may be performed on the raw steel golf shaft 104 prior to the painting of the raw steel golf shaft 104. Example pre-treatments include rust-proofing, etching, rinsing, degreasing, and other steel pre-treatments. The raw steel golf shaft 104, however, is not chrome plated.

After the paint is applied to the raw steel golf shaft 104, the raw steel golf shaft 104 is cured. The curing may or may not include heating.

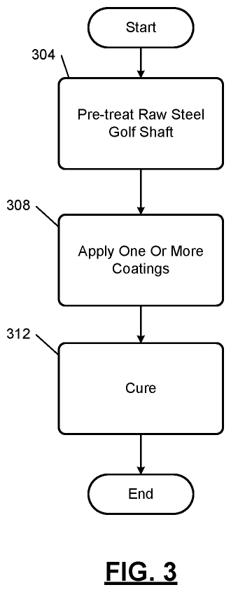

FIG. 3 includes an example method of applying one or more colored coatings to a raw steel golf (club) shaft. Control begins with 304 where optionally one or more pre-treatment processes may be performed on the raw steel golf shaft. Example pre-treatments include rust-proofing, etching, rinsing, degreasing, and other steel pre-treatments. The raw steel golf shaft, however, is not chrome plated.

At 308, one or more colored coatings are applied to the raw steel golf shaft. For example, one or more coats of the powder coating material may be applied to the raw steel golf shaft via powder coating. As another example, one or more coats of paint may be applied to the raw steel golf shaft. As yet another example, one or more layers of film may be deposited on the raw steel golf shaft via PVD.

At 312, the one or more colored coatings are cured. The curing may or may not involve heating. Because the coatings are applied to the raw steel golf shaft (as opposed to a steel golf shaft with a chrome plating), the coatings better adhere to the raw steel golf shaft. A finish of the colored coating may be (high) gloss. In various implementations, the finish of the colored coating may be flat, matte, semi-gloss, or (high) gloss. A layer of the coating may be transparent or translucent, for example, to increase a depth of color of the paint on the golf shaft. Alternatively, one the one or more colored coatings are cured, one or more coats of transparent or translucent paint can be applied. The transparent or translucent paint may increase a depth of the paint on the golf shaft.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

What is claimed is:

1. A method, comprising:
obtaining a raw steel golf shaft; and
applying a colored coating directly to exterior surfaces of the raw steel golf shaft using an applicator.

2. The method of claim 1 wherein the raw steel golf shaft does not include chrome plating.

3. The method of claim 1 further comprising coupling the raw steel golf shaft to a reference potential,
wherein applying the colored coating includes applying the colored coating by powder coating.

4. The method of claim 1 further comprising curing the colored coating.

5. The method of claim 1 further comprising pre-treating the raw steel golf shaft prior to the application of the colored coating.

6. The method of claim 5 wherein the pre-treating includes rust-proofing.

7. The method of claim 5 wherein the pre-treating includes etching.

8. The method of claim 5 wherein the pre-treating includes rinsing.

9. The method of claim 5 wherein the pre-treating includes degreasing.

10. The method of claim 1 wherein the applying the colored coating includes applying a colored paint directly to the exterior surfaces of the raw steel golf shaft.

11. The method of claim 10 wherein the paint includes a solvent based paint.

12. The method of claim 10 wherein the paint includes at least 0.5% acid by volume.

13. The method of claim 10 wherein applying the colored coating includes applying one or more layers of colored film using physical vapor deposition (PVD).

14. A golf club shaft comprising:
a raw steel tubular member; and
a colored coating applied directly to exterior surfaces of the raw steel tubular member.

15. The golf club shaft of claim 14 wherein the golf club shaft does not include chrome plating between the exterior surfaces of the raw steel tubular member and the colored coating.

16. The golf club shaft of claim 14 wherein the colored coating includes a colored powder coating.

17. The golf club shaft of claim 14 wherein the colored coating includes a colored paint.

18. The golf club shaft of claim 14 wherein the colored coating includes one or more layers of colored film.

19. The golf club shaft of claim 14 wherein the exterior surfaces of the raw steel tubular member are pre-treated prior to the application of the colored coating.

20. The golf club shaft of claim 19 wherein the pre-treatment includes at least one of rust-proofing, etching, rinsing, and degreasing.
